(19) United States
(12) Patent Application Publication
(10) Pub. No.: US 2005/0026452 A1
(43) Pub. Date: Feb. 3, 2005

(54) Etching method for manufacturing semiconductor device

(76) Inventors: Won-Jun Lee, Seoul-City (KR); Byoung-Moon Yoon, Gyeonggi-Do (KR); In-Seak Hwang, Gyeonggi-Do (KR); Yong-Sun Ko, Gyeonggi-Do (KR)

Correspondence Address: MARGER JOHNSON & McCOLLOM, P.C., 1030 S.W. Morrison Street, Portland, OR, 97205, US

(21) Appl. No.: 10/855,313

(22) Filed: May 26, 2004

(30) Foreign Application Priority Data
Jul. 31, 2003 (KR) 2003-53076
Sep. 22, 2003 (KR) 2003-65533

(51) Int. Cl. H01L 21/302; H01L 21/461

(52) U.S. Cl. 438/745

(57) ABSTRACT

A wafer having a dielectric layer and an electrode partially protruding from the top surface of the dielectric layer is provided. An etchant or chemical solution is applied to the dielectric layer and bubbles in the etchant are prevented from adhering to the electrode. In one embodiment, prior to etching, the protruding portion is covered with a buffer layer to prevent bubbles in the etchant from adhering to the electrode. Thus, the etchant can etch the dielectric layers without being blocked by bubbles included therein.

This application claims priority from Korean Patent Application No. 2003-53076, filed on Jul. 31, 2003, the contents of which are incorporated herein by reference in their entirety. This application also claims priority from Korean Patent Application No. 2003-65533, filed on Sep. 22, 2003, the contents of which are incorporated herein by reference in their entirety.

### BACKGROUND OF THE INVENTION

1. Field of the Invention

The present invention relates to methods for manufacturing semiconductor devices. More particularly, the present invention relates to etching methods for manufacturing a semiconductor device such as a capacitor lower electrode.

2. Description of the Related Art

In fabricating semiconductor devices such as dynamic random access memory (DRAM) devices, a chemical solution such as one containing HF and NH₄F (“LAL”) or a buffer oxide etchant (“BOE”) is commonly used to etch dielectric layers during various phases of semiconductor fabrication processes.

Unfortunately, bubbles of various sizes are undesirably generated in the chemical solution by, for example, additives such as a surfactant typically included in the chemical solution. These bubbles often adhere to the surface of a semiconductor substrate, creating serious problems such as an oxide un-etch or not-open phenomenon.

As the design rule decreases, this issue becomes more critical, considerably reducing the manufacturing yield. For example, as the shape of the capacitor lower electrode becomes more circular following the reduction of the design rule, the bubbles are easily trapped within the lower electrode, thereby creating various problems such as a not-open phenomenon.

Accordingly, an immediate need exists for a novel etching method that can overcome problems caused by air bubbles contained in the chemical solution.

### SUMMARY OF THE INVENTION

The present invention provides improved methods of etching dielectric layers using a chemical solution such as LAL without, for example, an un-etch or not-open phenomenon resulting from bubbles contained in the chemical solution.

According to one embodiment of the present invention, a wafer having a dielectric layer and an electrode partially protruding from the top surface of the dielectric layer is provided. A chemical solution or an etchant is applied to the dielectric layer and bubbles in the chemical solution are prevented from adhering to the electrode. In one aspect, prior to etching, a buffer layer is formed to cover the protruding portion to prevent bubbles in the chemical solution from adhering to the electrode.

As a result of the inventive principles disclosed herein, bubbles contained in the chemical solution can be prevented from adhering to, for example, a capacitor lower electrode during dielectric layer etching processes. Thus, the chemical solution such as LAL can etch the dielectric layers without being blocked by bubbles included therein. Therefore, device failures, such as one bit failure caused by an un-etched phenomenon, can be prevented to increase the manufacturing yield.

### BRIEF DESCRIPTION OF THE DRAWINGS

The objects and advantages of the present invention will become more apparent by describing in detail preferred embodiments thereof with reference to the attached drawings in which:

FIGS. 1A through 1G are cross-sectional views illustrating an etching method according to an embodiment of the present invention;

FIG. 2A is a cross-sectional view illustrating bubbles included in a chemical solution such as LAL being trapped in a circular capacitor lower electrode;

FIG. 2B is a cross-sectional view illustrating an unetched portion caused by the bubbles present in the chemical solution within the capacitor lower electrode;

FIG. 2C is a top view of capacitor lower electrode structures of a semiconductor device illustrating a closed storage node contact of FIG. 2B, showing a “not open” phenomenon; and

FIG. 3 is a schematic diagram showing a dipping method according to an embodiment of the present invention.

### DETAILED DESCRIPTION OF THE INVENTION

The present invention will now be described more fully with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete and will fully convey the concept of the invention to those skilled in the art. In the drawings, the shape of elements is exaggerated for clarity, and the same reference numerals in different drawings represent the same element.

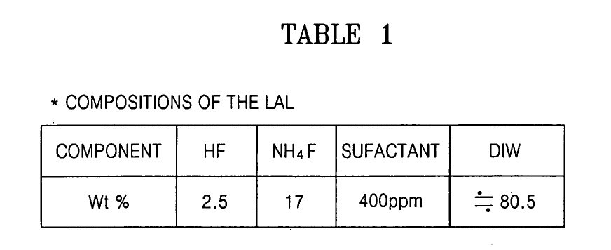

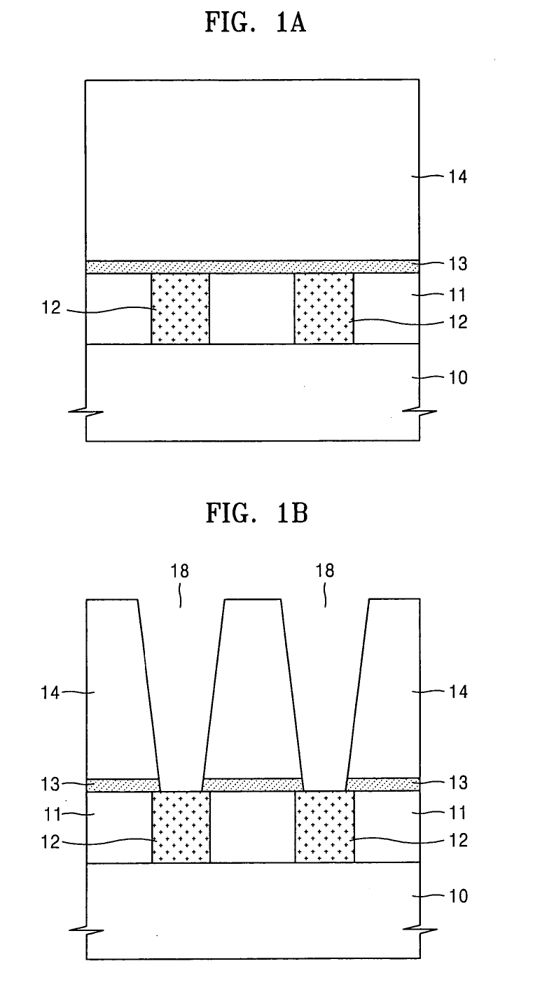

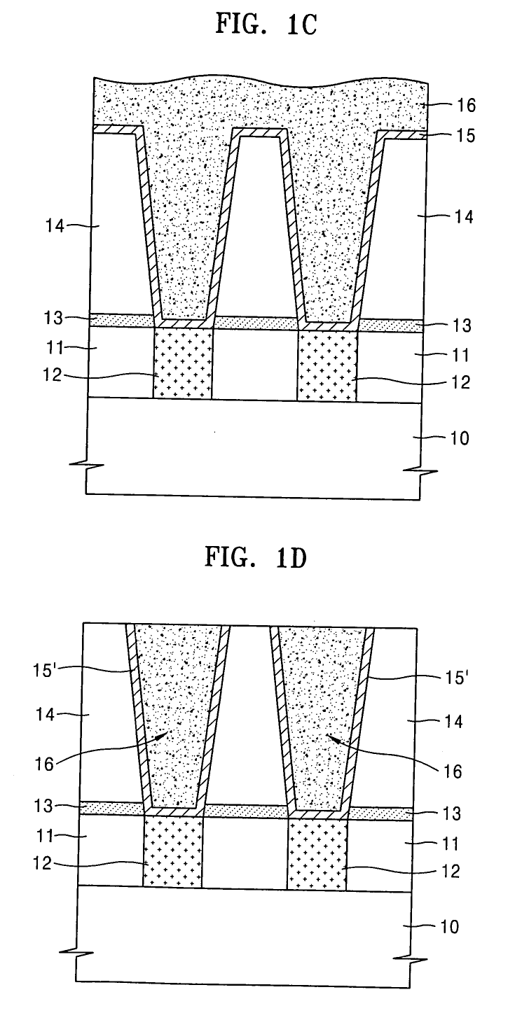

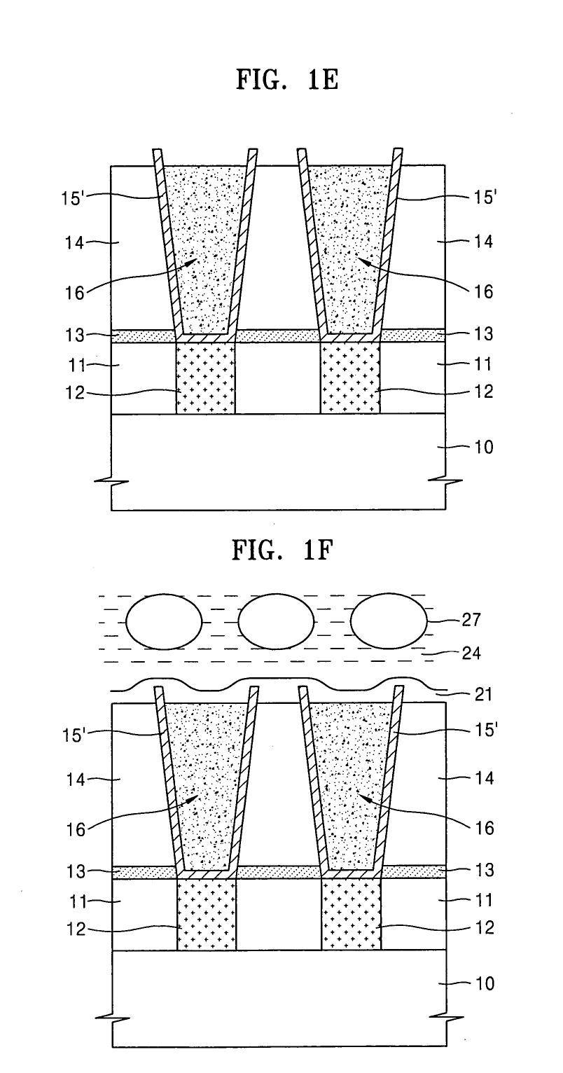

Referring to FIG. 1A, to form a capacitor of a semiconductor device such as dynamic random access memories (DRAMs), an interlayer insulating layer or a pre-metal dielectric layer 11 is formed on a wafer or semiconductor substrate 10. The interlayer insulating layer 11 is formed of a dielectric material such as oxide.

Although not shown, a lower structure such as source/drain regions and gate electrodes are formed on the semiconductor substrate 10 to form a transistor or a memory cell. Then, a storage node contact pad 12 is formed in the interlayer dielectric layer 11 to be electrically connected to a capacitor lower electrode to be formed thereon, using conventional techniques. The storage node contact pad 12 is also electrically connected to active regions of the semiconductor substrate 10.

Subsequently, the interlayer dielectric layer 11 is planarized. An etch stop layer 13 is then formed on the interlayer dielectric layer 11. The etch stop layer 13 has a high etch selectivity with respect to the first dielectric layer 14. These layers can be formed using conventional processes. The etch stop layer 13 can be formed of, for example, silicon nitride to a thickness between about 500 to 1,000 angstroms.

A first dielectric layer 14 is formed on the etch stop layer 13. The etch stop layer 13 serves as an end point during a subsequent etching lift-off process for removing the first dielectric layer 14, as well as second dielectric layer 16 to be formed thereon.

The first dielectric layer 14 is preferably formed of an oxide having a thickness between about 3,000 to 20,000 angstroms using a conventional technique such as a low pressure chemical vapor deposition (LPCVD) process. The first dielectric layer 14 can be a single layer of plasma-enhanced tetraethylorthosilicate (PE-TEOS) or a multilayer including the PE-TEOS layer.

Referring to FIG. 1B, the first dielectric layer 14 is etched or patterned to form a storage node opening 18 therein to expose a portion of the contact pad 12, using conventional photolithography and etching processes, with the etch stop layer 13 as an etch stop. The etch stop layer 13 remaining within the storage node opening 18 is removed.

Referring to FIG. 1C, a conductive layer 15 formed of a material such as doped polysilicon, Pt, Ru, or TiN, is deposited on the first dielectric layer 14 including the opening 18 and on the storage node contact pad 12 to form a capacitor lower electrode 15′. (FIG. 1D) Then, a second dielectric layer 16 is formed on the conductive layer 15 that is connected to the contact pad 12 and within the opening 18. The second dielectric layer 16 is preferably formed of oxide to a thickness between about 10,000 to 30,000 angstroms. Those skilled in the art will appreciate that other suitable dielectric materials can also be used to form the first and second dielectric layers 14, 16.

Turning to FIG. 1D, the first and second dielectric layers 14, 16 including the conductive layer 15 are planarized, until the top surface of the first and second dielectric layers 14, 16 are exposed, so as to form separated capacitor lower electrodes 15′.

The planarization process can be performed using conventional techniques such as chemical mechanical polishing (CMP) or an etching back process. Preferably, CMP comprises using a slurry having an etch selectivity between the capacitor lower electrode 15′ and the first and second dielectric layers 14, 16. Preferably, etching back comprises using an etchant having an etch selectivity between the capacitor lower electrode 15′ and the first and second dielectric layers 14, 16.

Referring to FIG. 1E, HF is preferably used to clean etching back or CMP residues resulting from the planarization process. An upper part of the capacitor lower electrode 15′ having, for example, a circle or elliptical shape may protrude from the surface of dielectric layers 14, 16 because of this wet cleaning process using HF, which selectively etches dielectric layers such as an oxide while substantially leaving the capacitor lower electrode formed of, for example, polysilicon. Other suitable chemicals can also be used to clean the residues as is known in the art.

Referring 1G, the first and second dielectric layers 14, 16 are preferably concurrently removed using a conventional lift-off process to complete the capacitor lower electrode 15′. In particular, the first and second dielectric layers 14, 16 are etched with a chemical solution such as LAL. During this wet etching process, LAL, the composition of which is disclosed in Table 1, is typically used. Other suitable wet etch chemicals besides LAL can be used as is known in the art.

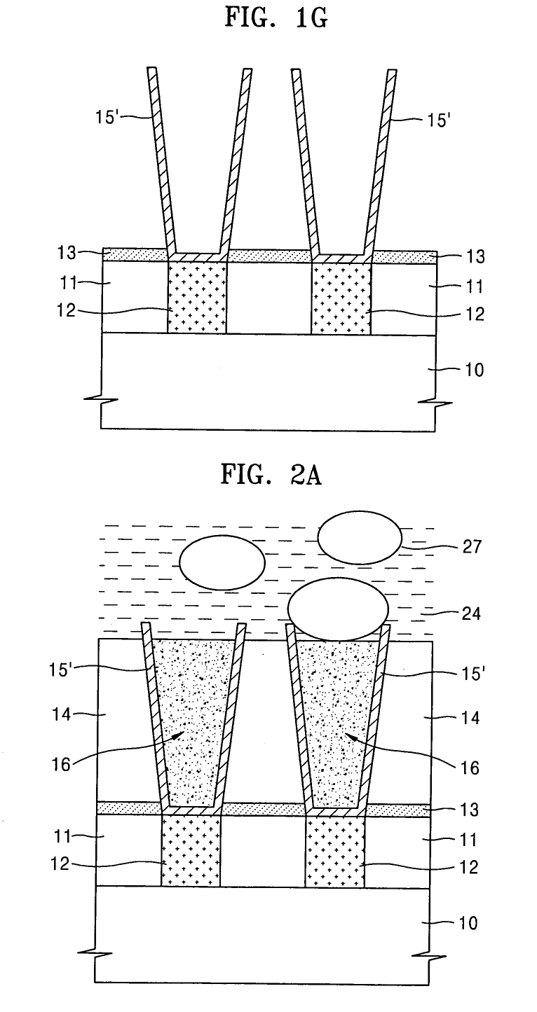

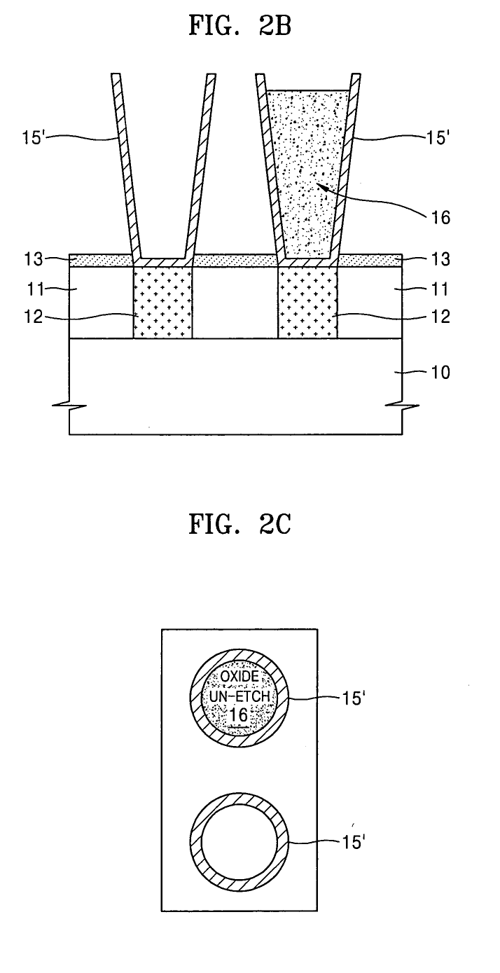

As shown in FIG. 2A, however, unfortunately, bubbles 27 contained in a chemical solution 24 such as LAL can easily adhere to the protruding portion of the lower electrode 15′, i.e., a portion that protrudes from top surfaces of the first and second dielectric layers 14, 16. This is especially true if the lower electrode 15′ is, for example, circular or elliptical in plan view because it can easily trap the bubbles 27.

This issue becomes more critical, as the design rule further decreases, because these undesirable bubbles 27 trapped in the capacitor lower electrode 15′ prevent the chemical solution 24 from contacting the second dielectric layer 16, thereby causing an un-etch or not open phenomenon, as shown in FIGS. 2B and 2C. In other words, a portion of the second dielectric layer 16 is left unetched because of the bubbles 27 present in the chemical solution 24, thus preventing the chemical solution 24 from contacting the second dielectric layer 16. This in turn prevents removal of the second dielectric layer 16.

Now turning to FIG. 1F, to deal with the problems described above, according to an embodiment of the present invention, prior to performing a conventional lift-off process, i.e., wet etching to remove the first and second dielectric layers 14, 16, a protruding portion or top end portion of the capacitor lower electrode 15′ is covered with a buffer layer 21 to prevent the bubbles 27 included in the chemical solution or etchant 24 from adhering to or contacting the electrode 15′ or to the semiconductor substrate 10. The buffer layer 21 may cover substantially all of the top surface of the substrate 10.

Preferably, the chemical solution 24 is applied to the dielectric layers 14, 16 before the buffer layer 21 that covers the protruding portion of the electrode 15′ dries substantially. More preferably, the chemical solution 24 is applied onto the dielectric layers 14, 16 within about 5 minutes after the protruding portion of the electrode 15′ is covered with the buffer layer 21. Most preferably, the chemical solution 24 is applied to the dielectric layers 14, 16 within about 2 minutes after the protruding portion of the electrode 15′ is covered with the buffer layer 21.

However, embodiments of the present invention are not limited to the above-described conditions, but one skilled in the art will appreciate that any other process conditions can be used as long as the buffer layer 21 is not substantially dried before the chemical solution 24 is applied to the dielectric layers 14, 16. In other words, the protruding portion of the electrode 15′ is preferably covered sufficiently with the buffer layer 21 to prevent bubbles included in the chemical solution 24 from adhering to the electrode 15′ at the commencement of the etching process. If the application of the chemical solution 24 to the dielectric layers 14, 16 is delayed after covering the protruding portion, the buffer layer 21 would be too dry and the effects of the present invention may not be obtained.

In contrast, in the prior art, the substrate 10 typically is substantially dried after the cleaning process, before etching dielectrics 14, 16. However, with the embodiments of the present invention, the surfaces of the substrate 10 are preferably sufficiently covered or wetted by the buffer layer 21 such that the bubbles 27 cannot be adhered to the electrode 15′ when the chemical solution 24 is applied to the dielectric layers 14, 16.

In one aspect of the present invention, once the etching process begins, the buffer layer 21 may not need to cover the protruding portion of the electrode 15′. The buffer layer 21 may be mixed with the chemical solution 24. Because this etching process can begin without the bubbles 27 being adhered to the electrode 15′, the prior art problems resulting from the bubbles 27 trapped within the electrode 15′ does not occur.

In one embodiment, to cover the electrode 15′ with the buffer layer 21, a hydrophilic liquid is applied over the protruding portion of the electrode 15′. Preferably, the hydrophilic liquid includes, but is not limited to, deionized water (DIW), H₂O₂, or O₃ water. The hydrophilic liquid preferably has substantially fewer bubbles or impurities compared to the chemical solution 24 so that the surfaces of the substrate 10 including the electrode 15′ can be sufficiently wetted or covered by the buffer layer 21 having a low surface tension.

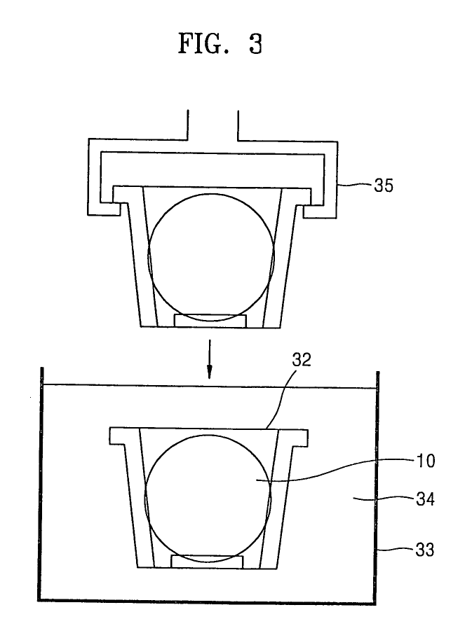

The buffer layer 21 is preferably formed by spraying the hydrophilic liquid over the top end portion of the electrode 15′. Alternatively, the buffer layer 21 may be formed by dipping the substrate 10 in a hydrophilic liquid 34 using, for example, a conventional wet-chemical bath 33, as shown in FIG. 3. In particular, the substrate 10 is preferably placed in a wafer carrier 32 and dipped into the hydrophilic liquid 34, using a conventional robot arm 35.

However, the present invention is not limited to the above-described embodiments. One skilled in the art will appreciate that other suitable methods to prevent the bubbles 27 from adhering to the electrode 15′ can be equally applicable to the application of the present invention.

As a result of the inventive principles disclosed herein, the bubbles 27 contained in the chemical solution 24 can be prevented from adhering to, for example, the capacitor lower electrode 15′ during dielectric etching processes. Thus, the etchant or chemical solution such as LAL can etch the dielectric layers 14, 16 without being blocked by the bubbles 27 included therein.

Therefore, with the embodiments of the present invention, device failures, such as one bit failure caused by an un-etched phenomenon, can be prevented. Therefore, the yield can be significantly increased.

While the present invention has been particularly shown and described with reference to a method for manufacturing a capacitor, this invention should not be construed as being limited thereto. Rather, the present invention can be applied to any wet etching process involving a chemical solution containing bubbles therein to etch any dielectric structure, in which an electrode, a conductive layer, or even a dielectric layer partially protrudes from the top surface of the dielectric structure, without departing from the spirit and scope of the present invention as defined by the following claims.

1. An etching method comprising:
providing a wafer having a dielectric layer and an electrode partially protruding from a top surface of the dielectric layer;
applying an etchant to the dielectric layer; and
preventing bubbles in the etchant from adhering to the electrode, wherein preventing the bubbles from adhering to the electrode comprises covering the protruding portion of the electrode with a buffer layer.

2. The method of claim 1, wherein the buffer layer comprises a hydrophilic liquid.

3. The method of claim 2, wherein the hydrophilic liquid is chosen from DIW, H₂O₂, or O₃ water.

4. The method of claim 1, wherein applying the etchant comprises applying the etchant onto the dielectric layer before the buffer layer substantially dries.

5. The method of claim 1, wherein applying the etchant is performed within about 5 minutes after covering the protruding portion with the buffer layer.

6. The method of claim 5, wherein etching the dielectric layer is performed within about 2 minutes after covering the protruding portion with the buffer layer.

7. The method of claim 1, wherein preventing bubbles from adhering to the electrode comprises covering substantially all of the top surface of the substrate including the protruding portion of the electrode with the buffer layer.

8. The method of claim 1, wherein the dielectric layer is formed of oxide and the etchant comprises Hydrogen, Nitrogen, Fluorine, and DIW.

9. The method of claim 8, wherein the etchant comprises HF, NH₄F, DIW and a surfactant.

10. An etching method comprising:
providing a wafer having a dielectric layer and an electrode partially protruding from the top surface of the dielectric layer;
etching the dielectric layer with a chemical solution; and
before etching, covering the protruding portion with a buffer layer to prevent bubbles in the chemical solution from adhering to the electrode.

11. The method of claim 10, wherein etching the dielectric layer comprises applying the etchant onto the dielectric layer before the buffer layer substantially dries.

12. The method of claim 10, wherein etching the dielectric layer is performed within about 5 minutes after covering the protruding portion with the buffer layer.

13. The method of claim 12, wherein etching the dielectric layer is performed within about 2 minutes after covering the protruding portion with the buffer layer.

14. The method of claim 10, wherein the buffer layer comprises a hydrophilic liquid.

15. The method of claim 14, wherein the hydrophilic liquid is chosen from DIW, H₂O₂, or O₃ water.

16. The method of claim 10, wherein covering the protruding portion comprises spraying the buffer layer over a top end portion of the electrode.

17. The method of claim 10, wherein covering the protruding portion comprises dipping the wafer in a buffer layer solution that forms the buffer layer.

18. The method of claim 10, wherein the chemical solution comprises HF or NH₄F.

19. An etching method comprising:
forming a first dielectric layer on a semiconductor substrate;
forming an opening in the first dielectric layer;
depositing a conductive layer on the first dielectric layer including the opening;
depositing a second dielectric layer overlying the conductive layer within the opening;
planarizing the resulting structure including the conductive layer, until the top surface of the first layer is exposed, to form a capacitor lower electrode having a top end portion; and
etching the first and second dielectric layers with a chemical solution and preventing bubbles in the chemical solution from adhering to the electrode.

20. The method of claim 19, wherein preventing bubbles comprises covering the protruding portion of the electrode sufficiently with a buffer layer to prevent bubbles included in the chemical solution from adhering to the electrode.

21. The method of claim 19, wherein planarizing comprises chemical mechanical polishing (CMP).

22. The method of claim 21, wherein CMP comprises using a slurry having an etch selectivity between the lower electrode and the dielectric layers.

23. The method of claim 19, further comprising cleaning the first and second dielectric layers to reduce etch residues, after planarizing the resulting structure and before covering the protruding portion.

24. The method of claim 23, wherein cleaning comprises using HF.

25. The method of claim 19, wherein the capacitor lower electrode is substantially circular or elliptical in plan view.

26. An etching method comprising:
forming a first dielectric layer on a semiconductor substrate;
forming an opening in the dielectric layer;
depositing a conductive layer on the first dielectric layer including the opening;
depositing a second dielectric layer overlying the conductive layer within the opening;
planarizing the resulting structure including the conductive layer, until the top surface of the first layer is exposed, to form a capacitor lower electrode having a top end portion;
after planarizing the resulting structure, creating a buffer layer; and
thereafter, etching the first and second dielectric layers with a chemical solution, wherein the buffer layer prevents bubbles in the chemical solution from adhering to the top end portion of the electrode.

27. The method of claim 26, further comprising cleaning the first and second dielectric layers to remove etch residues, after planarizing the resulting structure and before creating the buffer layer.

28. The method of claim 27, wherein cleaning comprises using HF.

29. The method of claim 26, wherein the capacitor lower electrode is substantially circular or elliptical in plan view.

30. The method of claim 26, wherein etching the first and second dielectric layers is performed before the buffer layer that covers the top end portion is substantially dried.

31. The method of claim 26, wherein creating the buffer layer comprises forming a hydrophilic liquid layer over the top end portion of the electrode.

32. The method of claim 31, wherein the hydrophilic liquid layer is formed by a liquid chosen from DIW, H₂O₂, or O₃ water.

33. The method of claim 31, wherein forming the hydrophilic liquid layer comprises spraying a hydrophilic liquid over the top end portion of the electrode.

34. The method of claim 31, wherein forming the hydrophilic liquid layer comprises dipping the substrate in a hydrophilic liquid.
